(19) United States
(12) Patent Application Publication
(10) Pub. No.: US 2025/0336701 A1
(43) Pub. Date: Oct. 30, 2025

(54) METHOD AND APPARATUS FOR INTRODUCING A SUBSTRATE INTO A NIP

(71) Applicant: LUMET TECHNOLOGIES LTD., Rehovot (IL)

(72) Inventors: Benzion LANDA, Nes Ziona (IL); Yosef SHACHAK, Kfar Saba (IL); Jitschak SANDERS, Givat Shmuel (IL); Ofir NEGER, Rishon LeZion (IL)

(21) Appl. No.: 19/260,882

(22) Filed: Jul. 7, 2025

Related U.S. Application Data
(62) Division of application No. 17/766,721, filed on Apr. 5, 2022.

(30) Foreign Application Priority Data
Oct. 22, 2019 (GB) 1915299.0

(51) Int. Cl. H01L 21/677; H01L 21/687

(52) U.S. Cl. CPC H01L 21/67706; H01L 21/67715; H01L 21/68742

(57) ABSTRACT

A system is disclosed for transferring a substance pattern to a substrate. The system comprises a nip defined between a roller and an opposing surface, a web carrying the substance pattern driven to pass the nip with a predetermined velocity, and an endless conveyor for transporting the substrate towards the nip, the substrate passing through the nip at the same time, and with the same speed, as the web in order for the substance pattern to be transferred from the web to the substrate. Upon gripping of the substrate by the nip, no further force is applied by the transport conveyor, thereby avoiding compression of the substrate. The endless transport conveyor can be formed with at least one projection configured to engage a trailing edge of the substrate and can be driven to push the substrate towards the nip with a velocity less than the velocity of the web.

### RELATED APPLICATION

This application is a divisional application of U.S. patent application Ser. No. 17/766,721, filed on Apr. 5, 2022, which is the U.S. national stage of International Patent Application No. PCT/IB2020/059931, filed on Oct. 22, 2020, which claims Paris Convention priority from GB Patent Application No. 1915299.0 filed on Oct. 22, 2019, the contents of all foregoing applications being incorporated by reference in their entirety as if fully set forth herein.

### FIELD

The present disclosure relates to application of a substance pattern to a substrate by transfer from a flexible web.

### BACKGROUND

In the manufacture of certain products, there arises a need to apply a substance pattern to a surface of a substrate. For example, in the manufacture of solar cells, circuit boards, touch screens and radio frequency identification (RFID) antennas, amongst other items, one may wish to apply to a substrate a substance that comprises a composition containing particles of an electrically conductive material, and typically a binder maintaining the particles in a desired shape (e.g., pattern of lines, cross-section of lines, etc.) and/or an adhesive which may enhance adherence to the intended substrate or facilitate any functional interaction therewith. The substrate may, for instance, be a semiconductor wafer in the case of a solar cell, or it may be an electrically insulating substrate in the case of a printed circuit board. While such substrates are typically rigid and planar, flexible and/or non-flat (e.g., curved) substrates may also be used. In some cases, for example for an RFID device, it may be desired to apply a substance pattern directly onto a three-dimensional item, such as part of the body of a piece of equipment, whereupon the surface may be flat or curved.

Various methods are known for applying a substance pattern to a substrate. Generally, the substance pattern is formed directly on the substrate. In some methods, where a pattern of a substance is not intended to cover the entire surface, selective deposition of a substance may be performed to achieve a desired pattern, for instance by screen-printing. In other methods, the entire surface of the substrate may be coated with the substance, then part of the substance may be selectively removed, such as by etching or laser ablation, to leave the desired pattern. Each of these approaches has its own advantages and disadvantages.

The present Applicant has previously proposed, in WO 2018/020479 and WO 2018/020481, forming the substance pattern on the substrate by first filling grooves formed in a flexible web with the substance and subsequently transferring the pattern from the flexible web to the substrate. WO 2018/020483, discloses an apparatus for transferring a pattern of a composition containing particles of an electrically conductive material and a thermally activated adhesive from a surface of a flexible web to a surface of a substrate, the apparatus comprising:
i. respective drive mechanisms for advancing the web and the substrate at the same time through a nip at which a pressure roller acts to press the surfaces of the web and the substrate against one another,
ii. a heating station for heating at least one of the web and the substrate prior to, or during, passage through the nip, to a temperature at which the adhesive in the composition is activated when the surfaces are in contact with one another,
iii. a cooling station for cooling the web and the substrate after passage through the nip, and
iv. a separating device for peeling the web away from the substrate after passage through the cooling station to leave the pattern of composition adhered to the surface of the substrate.

When the above apparatus is used to print a pattern by transfer at speed on fragile (e.g., thin and brittle) substrates, such as semiconductor wafers, the substrates risk being damaged or broken at the time of their being fed into the nip.

### SUMMARY

With a view to mitigating the foregoing problem, there is provided, in accordance with a first aspect of the present disclosure, a system for transferring a substance pattern to a substrate, the system comprising a web carrying the substance pattern, a web drive mechanism for driving the web through a nip between a roller and an opposing surface, and a transport conveyor for advancing a substrate towards the nip for the substrate to be gripped in the nip and frictionally driven through the nip at the same time, and with the same velocity, as the web, the web being pressed against a surface of the substrate during passage through the nip to cause the substance pattern to transfer from the web to the substrate, characterised in that upon the substrate being gripped in the nip, no further force is applied by the transport conveyor to the substrate to advance the substrate towards the nip, thereby avoiding compression of the substrate.

In some embodiments of the system, the transport conveyor does not apply to the substrate a force in a direction to advance the substrate towards the nip, the compression avoided being a lengthways compression of the substrate between the nip and the transport conveyor.

In some embodiments of the system, the transport conveyor includes at least one projection to engage a trailing edge of the substrate and the transport conveyor is driven to advance the substrate towards the nip with a velocity lower than that of the passage of the substrate through the nip, whereby the trailing edge of the substrate automatically disengages from the projection upon engagement of the leading edge of the substrate within the nip.

A feed conveyor can be provided to place substrates individually into a volume swept by the projections of the transport conveyor so that the trailing edge of the substrate can be engaged by a projection of the transport conveyor and thereby loaded onto the transport conveyor.

The purpose of the nip in the present invention is to apply a force urging the web and the substrate against one another to ensure transfer of the substance patterns from the web to the substrates. The substrate is gripped in the nip in absence of forces being applied by the transport conveyor, thereby avoiding compression of the substrate between the nip and the transport conveyor. Each side of the nip may either be a roller (e.g., a pressure roller) or a low friction surface (e.g., opposing surface) relative to which the substrates or the web can slide easily. In embodiments of the invention described herein, at least the side of the nip in contact with the web is constituted by a roller.

If substance patterns are to be transferred to both sides of a substrate from two different webs, both transfers may either take place at the same time while the two web and the substrate pass through the same nip, or they may take place consecutively through two separate nips. In the former case, the nip can be constituted by two rollers facing one another, the two rollers being in one embodiment additionally symmetrical in size.

In accordance with a second aspect of the invention, there is provided a method of introducing a substrate into a nip defined between a roller and an opposing surface through which the substrate is driven, in which method the substrate is advanced towards the nip by means of a transport conveyor that is configured to cease applying a force to the substrate upon engagement of the leading edge of the substrate within the nip, so as to avoid the substrate being compressed.

In some embodiments of the method, the transport conveyor is configured to cease applying a force to the substrate in a direction to advance the substrate towards the nip so as to avoid lengthways compression of the substrate between the nip and the transport conveyor.

In some embodiments of the method, the transport conveyor is formed with a projection to engage a trailing edge of the substrate to push the substrate towards the nip, and the velocity of the conveyor is set to less than the velocity passage of the substrate through the nip, such that on entry of the leading edge of the substrate into the nip the trailing edge separates from the projection of the transport conveyor.

These and additional benefits and features of the disclosure, which are inter alia set forth in the appended claims, will be better understood with reference to the following detailed description taken in conjunction with the figures.

### BRIEF DESCRIPTION OF THE DRAWINGS

Some embodiments of the disclosure will now be described further, by way of example, with reference to the accompanying figures, where like reference numerals or characters indicate corresponding or like objects. The description, together with the figures, makes apparent to a person having ordinary skill in the art how some embodiments of the disclosure may be practiced. The figures are for the purpose of illustrative discussion and no attempt is made to show structural details of an embodiment in more detail than is necessary for a fundamental understanding of the disclosure. For the sake of clarity and convenience of presentation, some objects depicted in the figures are not necessarily shown to scale.

In the Figures:

FIG. 1 illustrates a transferring system, as described in WO 2018/020483, for applying (e.g., electrically conductive) patterns to opposite sides of a substrate which can be modified according to the present teachings, in particular to include a novel apparatus for delivering a substrate;

FIG. 2 shows a perspective view of a feeding mechanism for delivering a substrate to a nip at a correct time and velocity in accordance with an embodiment of the present disclosure;

FIG. 3 is a perspective section view of the apparatus shown in FIG. 2;

FIG. 4 is a perspective section view of the apparatus of FIG. 2, the section taken being in a perpendicular plane to that of FIG. 3;

FIGS. 5A and 5B schematically depict nips to which a substrate feeding mechanism according to the present disclosure may deliver substrates for the application of a substance pattern on one or more of its sides; and

FIG. 6 schematically depict how pressure rollers and backing surfaces may be further coated and combined according to various embodiments of the present disclosure so as to form nips that may be implemented with a substrate feeding mechanism, such as illustrated inter alia in FIGS. 5A and 5B.

### DETAILED DESCRIPTION

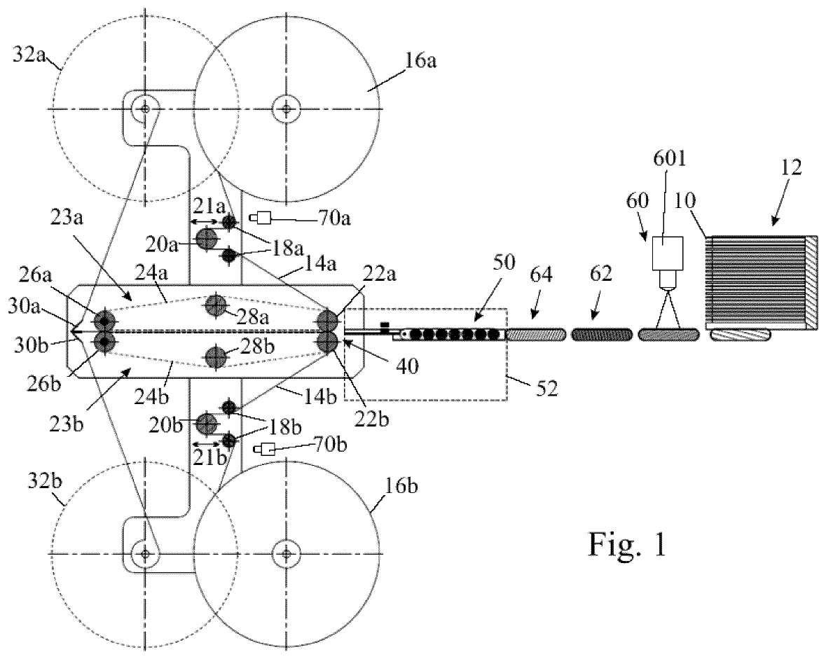

The apparatus of FIG. 1, as described in more details in WO 2018/020483, is intended to apply a substance pattern to opposite sides of substrates 10, e.g., drawn from a stack 12 or from a cassette. For example, the substance of the pattern may be a composition that contains particles such as electrically conducting particles (e.g., made of metals or suitable alloys) and a thermally and/or pressure activated adhesive (e.g., a hot melt polyamide adhesive). Such patterns can be rendered electrically conductive, for example by application of energy to sinter the composition. The composition may not require the application of energy to become conductive, and in some cases electrical conductivity may not be required, the pattern, for example, only being ornamental. If the pattern is to be treated to develop its desired functional and/or esthetical effect, for instance is to be heated to become electrically conductive, or to be fused or cured to increase adhesion to the substrate, this treatment is typically performed following transfer of the pattern from the web to the substrate.

Thus, in one example considering a functional pattern able to conduct electricity, the substrates 10 may be semiconductor wafers onto which the apparatus applies the front and back electrodes of the desired end-product, which may be a solar cell. The transferred patterns may constitute at least part of the patterns desired on the substrate, for example they may form a grid-like pattern of fingers of a solar cell, transversal bus bars optionally being separately applied by a similar or different method. The two conductive patterns applied on opposite sides commonly differ from one another but may need to be each correctly aligned with the substrate (hence also with one another on each side of the substrate). In another example, the end-item may exclude a semiconductor wafer (e.g., may be an electrically insulating substrate, plastic, glass, etc.), may have functionality other than of a solar cell (e.g., functionality of a circuit board, an RFID antenna, a display, a touch screen, etc.), and/or may be purely decorative.

In the non-limiting example of substrate drive mechanism illustrated in FIG. 1, substrates 10 are dispensed one at a time from a stack 12 to an inspection station 60 where the upper surfaces of the substrates can be analysed optically for defects by a camera 601. In a selection station 62 that follows, substrates found to be defective can be ejected.

Substrates 10 (preferably pre-inspected to be without defects) are advanced by a conveyor and alignment device 50 where they can be heated by a heater 52. Optionally an adhesive adapted to improve the transfer of the pattern from the web and/or its retention on the substrate may be applied to the surface of the substrates or to parts thereof. After being heated, if desired, and correctly positioned and oriented, the substrates 10, which may optionally be coated at least in part with an adhesive, are fed into a nip 40 defined between two pressure rollers 22a and 22b, which may be identical and symmetrical, as illustrated in FIG. 1.

While the inclusion of an inspection station 60 and a selection station 62 to detect and eject defective substrates is recommended, such stations are not essential for the operation of the apparatus, being only preferable from a quality control standpoint. Stations fulfilling similar roles downstream of the nip, e.g., following the peeling of the flexible web, can optionally be additionally or alternatively included to detect defective patterns and eject substrates bearing such defects, and/or to sort into various bins in accordance with quality level.

In the event that the apparatus does comprise stations 60 and 62 upstream of the nip, it can be desired to further include an accelerating station 64 allowing a non-defective substrate being drawn after a defective one, which was therefore ejected, to reach the nip in synchronism with the pattern(s) of the web(s). Such accelerating station 64 may therefore prevent an “empty” feeding of the web at the nip, in absence of a substrate. Such an accelerating station is, however, not essential as such empty feeding can be tolerated or mitigated by alternative means, such as adding a substrate pre-selected as flawless from a buffer of such non-defective wafers, or by any like solution.

Similar inspection stations may be placed at additional positions in the apparatus and configured to send relevant instructions to the system in response to the situations they are aimed to detect and signal. For instance, in case of substrate misfeeding, which can be detected by a sensor positioned upstream to the nip, the inspection station may cause the interruption of substrate feeding, the deceleration of web feeding and the cessation of operation of the apparatus (at least for the duration of the removal of the misfed substrate).

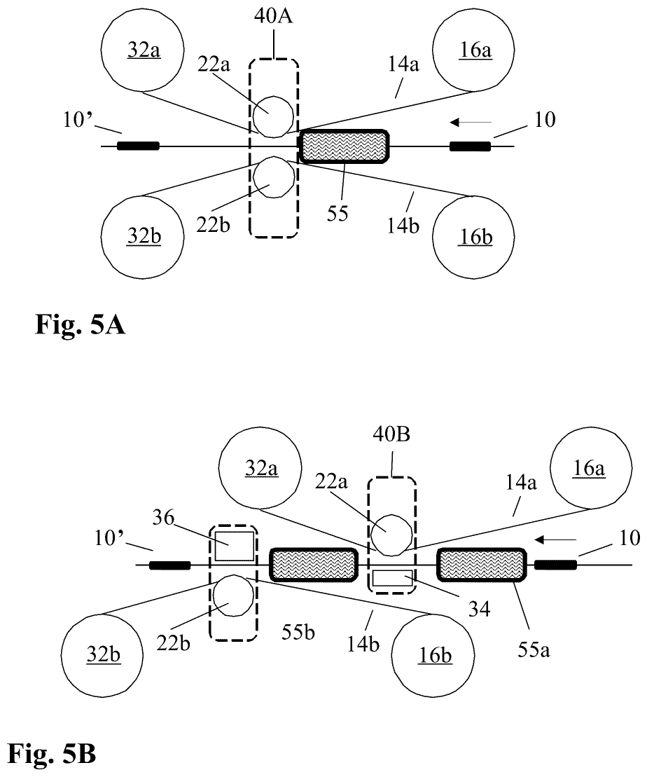

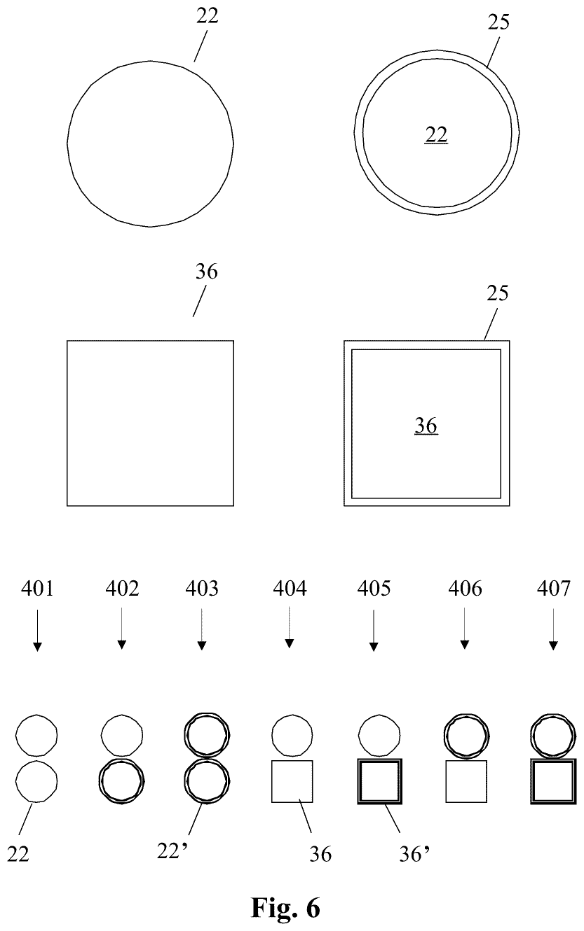

The patterns of substance that include the desired composition that are to be transferred to the substrates are carried by two flexible webs 14a and 14b, which as mentioned need not be the same. As can clearly be seen from FIG. 1, the drive mechanisms of the two webs 14a and 14b can be mirror images of one another, but this need not be the case and alternative configurations are possible, as illustrated in, and described below by reference to FIGS. 5 and 6. To avoid repetition, reference numerals without a suffix will be used in the present description to refer generically to components of both web drive mechanisms but suffixes “a” and “b” are used in the drawings to distinguish between the upper and lower drive mechanisms.

Each web 14 is drawn from a supply roll 16, for instance, by way of idler rollers 18 and a dancer 20 that can move from left to right as represented by an arrow 21. The dancer 20 can serve to tension the web and also to ensure correct registration 14 of the patterns on the web with the substrates 10. When two webs are employed to apply substance patterns on opposite sides of the substrate, the tension rollers that may be present along each of their respective path can serve to achieve registration between the patterns carried by both webs.

Typically, when the web 14 is drawn from supply roll 16 the composition is level with the surface of the web and generally, but not necessarily, essentially dry. Optionally, an adhesive adapted to improve the transfer of the pattern from the web and/or its retention on the substrate may be applied to the web 14 subsequent to the drawing of the web 14 from supply roll 16 and prior to its contacting the substrate (e.g., upstream of the nip). The web 14 passes between the two pressure rollers 22 that define the nip 40 into which substrates 10 are fed. Within the nip 40, the substance/composition pattern on the web 14 is pressed against a surface of the substrate 10 resulting in the pattern of substance/composition adhering to the substrate. The web 14 may then pass through an optional cooling station 23, between two rollers 26, and be separated from the substrate 10, e.g., by a separating device 30 or by forming a take-up angle suitable for separation. After separation from the substrate 10 for instance by the device 30, the web can be rewound on a take-up roll 32. If desired, the take-up 32 roll can be returned to the web supplier for recycling.

In the event that the take-up roll 32 is discarded, the web 14 may be referred to as a disposable web or flexible membrane. The process employing the webs as herein disclosed may be referred to as a “roll to roll” method, the webs from which patterns are transferred to the substrates being drawn from supply roll 16 and rewound on take-up roll 32.

If peeling is not desired, for example, because web 14 may additionally serve to protect substrate 10, separating device 30 and take-up roll 32 may be omitted from the apparatus. The term “transferred” as used herein for a pattern of composition and variants thereof should be understood to also cover embodiments where the web and the substrate are not separated from one another. If cooling is not desired, for example, because the substance pattern is transferred by pressure and/or the transfer is not performed at an elevated temperature and/or the web need not be rapidly separated from the substrate, cooling station 23 may be omitted from the apparatus or turned off.

For the purpose of ensuring correct registration of the patterns of substance/composition with the substrates 10, optical sensors 70 may be provided to sense the location of the patterns on the web 14, e.g., upstream of the idler rollers 18. The type of sensors, their positioning along the paths followed by each of the webs and the substrate, the signals they may provide to a system adapted to control and take responsive actions and the responses they may trigger to different parts of the apparatus in order to ensure correct registration or to reduce erroneous registration within tolerance are known to the skilled persons and need not be detailed herein.

By way of non-limiting example, a controller may set a first velocity to a web and adjust a second velocity of the substrates while on the transportation conveyor, upon (and prior to) engagement of the substrate into the nip. The circumferential velocity of the at least one pressure roller of the nip is essentially the same as the linear velocity of the web, so that when comparing the velocity of the substrate to the velocity of the nip, reference is made to the corresponding linear velocity of each. The Applicant avoids lengthways compression of the substrates inter alia by ensuring that the nip has a velocity greater than the velocity of the substrate upon engagement therewith. This can be achieved either by increasing the velocity of the web with respect to the substrate, or by reducing the velocity of the substrate with respect to the web.

While the figures schematically illustrate an apparatus allowing simultaneous transfer of two patterns onto respective opposite surface of the substrate, the skilled person can readily appreciate how a similar apparatus can be prepared to transfer patterns of substance/composition on a single substrate side or on a single substrate side at a time (e.g., two nips being required to sequentially apply a pattern from a first web to a first side and a pattern of a second web on a second side). In such a case, nip 40, whether sole, first or second nip of the apparatus, for instance, can be formed between a single pressure roller 22 and a backing support 34 for substrate 10. The backing support may be static (e.g., a plate, the pressure roller and/or the movement of the web driving the displacement of the substrate thereupon) or may be in motion (e.g., a conveyor adapted to transport the substrate at a velocity selected to match the relative movement of the respective web). As a nip includes at least one pressure roller 22 (e.g., 22a), the surface against which pressure is applied may be referred to as an opposing surface or a backing surface 36, which as mentioned can be a second pressure roller (e.g., 22b) or a backing support 34, and may provide for a static or a dynamic surface upon closing of the nip in operation of the system.

FIGS. 5A and 5B illustrate a number of nip configurations in a highly schematic manner. FIG. 5A depicts a system wherein a substrate 10 is fed to a nip 40A in the direction of the arrow, to receive on its two sides substance patterns delivered respectively by webs 14a and 14b, each being supplied by a supply roll 16a or 16b and ultimately taken up by rewound rolls 32a or 32b, accordingly. The substrate 10 is fed to nip 40A formed by two pressure rollers 22a and 22b via a feeding mechanism 55 to be later detailed and exits the nip following transfer of patterns as 10′.

FIG. 5B depicts alternative systems wherein a substrate 10 is fed to a nip 40B in the direction of the arrow, to receive on a single one of its two sides substance patterns delivered by web 14a being supplied by a supply roll 16a and taken up by rewound roll 32a. The substrate is fed to nip 40B formed by pressure roller 22a and backing support 34 via a feeding mechanism 55a. The substrate may optionally sequentially enter a second nip 40C formed by pressure roller 22b and backing surface 36 via a feeding mechanism 55b. Nip 40C allows for the application of a second substance pattern on the other side of the substrate, the second patterns being delivered by web 14b supplied by a supply roll 16b and taken up by rewound roll 32b. Nips 40A and 40B are examples of nip 40C and while the configuration of nip 40A may be preferred for synchronous application of substance patterns on both sides of a substrate, all three configurations may be used to apply a pattern on a single side of the substrate or to sequentially apply a pattern one side at a time.

Regardless of nip configuration, the pressure rollers 22 and backing surfaces 36 (e.g., backing supports 34) composing the nip 40 may be configured to suit the webs and substrates intended to pass therebetween. For instance, they may form suitable gaps, or have suitable dimensions, shapes or surface topography, suitable friction properties, suitable compressibility (e.g., to urge intimate contact between the web and a face of the substrate), suitable hardness (e.g., adapted to the substrate mechanical properties), and like considerations readily appreciated by a skilled person. Such properties of the pressure rollers or backing supports may be inherent to the part or provided by a suitable coating of the part.

In some embodiments, pressure roller 22 (or a backing support thereto) can be coated with a material (e.g., a polymeric compound or blend) so as to provide on its outer surface an external layer 25 having a hardness of no more than 100 Shore A, no more than 90 Shore A, no more than 80 Shore A, no more than 70 Shore A, no more than 60 Shore A, no more than 50 Shore A, or no more than 40 Shore A. In some embodiments, pressure roller 22 has an outer surface hardness of at least 10 Shore 00, at least 30 Shore 00, at least 50 Shore 00 (which approximately correspond to 10 Shore A), at least 20 Shore A, or at least 30 Shore A.

In some embodiments, pressure roller 22 (or a backing support thereto) can be coated with a material so as to provide on its outer surface an external layer 25 alternatively or additionally serving as a compressible layer adapted to ensure the proper contacting of the surfaces of the web and the substrate.

FIG. 6 schematically illustrates these alternatives of having a pressure roller 22 or a backing surface 36 uncoated or coated with an external layer 25. For the sake of the possible combinations of the same, being depicted by nips 401 to 407, the coated versions of the pressure roller and the backing surface shall be referred to in this figure by 22′ and 36′ respectively.

The parts forming the nips (e.g., pressure roller 22 and backing surface 36) are preferably capable of disengagement one from another, allowing for instance to adjust a distance between them (e.g., moving at least one of the two pressure rollers 22a and 22b one toward or away from the other), such as for adapting the nip gap to the substrate and/or webs thickness, or for threading a web, or for removing a misfed substrate, and like conventional operation and maintenance that may be required at a nip.

As closing of a nip to form a gap suitable for transfer may cause a mild (typically backward) displacement of the web contacted by the part being moved, the webs may be accordingly positioned prior to closing to take this phenomenon into account. For instance, one of the two webs 14 may be intentionally advanced with respect to the other in a manner which causes the patterns carried by the webs to be non-aligned prior to the closing of nip 40, so that the webs and their respective patterns be correctly aligned (e.g., within tolerance) upon closing of the nip. The extent of intentional pre-nip-closing misalignment due to provide correct alignment following nip closing can be calculated based on nip configuration and operation or can be empirically determined. Correct alignment following closing of the nip can be determined visually prior to starting or restarting the web drive mechanisms or with the assistance of suitable sensors in operation of the apparatus.

The cooling of the substrates to which the webs are still attached in the cooling station 23 is effected in the illustrative figure by an endless belt 24 that also passes through the nip between the rollers 22 and the nip between the rollers 26 and further passes over an idler roller 28. Other cooling methods and devices may be alternatively used for this purpose. In some of such methods and devices, rollers 26 may be omitted. In an alternative approach, the web (and in turn to some extent the substrate) may be cooled by conduction by being brought into thermal contact with a “static” heat sink (e.g., a conventional heat exchanger passively or actively refrigerated by a fluid, and optionally including a number of fins to facilitate heat dissipation). For example, the heat sink may extend between the nip and a point on the path at which the web is separated from the substrate (e.g., by separating device or by web forming an angle with the substrate sufficient to achieve separation). The web(s) and/or the substrate may be maintained in thermal contact with the heat sink by way of one or more rollers urging such contact. In some embodiments, these roller(s) may additionally act as a portion of the heat sink. For instance, such rollers may optionally be cooled (e.g., liquid cooled).

Regardless of the means and methods used to cool the web(s) and/or the substrate, such cooling is adapted so that the web reaches the separation point (e.g., the separating device) at a particular temperature, so as to facilitate the separation of the web away from the substrate and/or the adhesion of the pattern of composition to the surface of the substrate. Without wishing to be bound by any particular theory, it is believed that peeling the web from the substrate at a temperature below the softening temperature of the web and below the softening temperature of the composition (e.g., the softening temperature of polymers comprised in the composition, for instance adhesives and in particular thermally activated ones) may assist these processes. For example, the temperature of the web following cooling and upon separation can be at most 60° C., at most 50° C., or at most 40° C.

Following this rationale, a cooling station may, in some embodiments, not be necessary to the apparatus. For instance, if the transfer is effected at relatively moderate temperatures at which the pattern may sufficiently transfer to the substrate and attach thereto, a cooling step may not be required. This can the case, for instance, if the adhesive of the composition is a pressure sensitive adhesive, or if an additional adhesive is applied to the substrate, the webs, or selected regions thereof.

When using the apparatus shown in FIG. 1 at elevated speed, damage (e.g., breakage) of substrates 10, when thin and brittle, was observed in a commercially significant proportion. While breakage of relatively fragile substrates can be reduced or prevented by uniform speed reduction of the apparatus, such approach accordingly reduces productivity. The present disclosure provides an alternative feed mechanism that is intended to replace corresponding components upstream of the nip 40 to achieve a lower breakage rate, preferably less than 1.5%. While the feed mechanism of the present invention is advantageous for relatively fragile substrates, its use need not be limited to such substrates, since being capable of transferring patterns at relatively high velocities increases productivity regardless of the substrate type. The apparatus downstream of the nip 40, which can be, for instance, essentially as described in WO 2018/020483 and US 2019/0174635, may be retained without modification or be adapted as described herein.

Likewise, components upstream of the nip only facilitating the operation of the alternative feed mechanism according to the present teachings, or not being related thereto, may be preserved. For instance, a subsystem ensuring the timely delivery of a pattern carried by a flexible web can be similar in principle and architecture to one previously described by the Applicant, or otherwise known in part from the art, or adapted as further described herein. Such known components shall not be detailed herein and interested readers are referred inter alia to WO 2018/020483 and US 2019/0174635, which are incorporated by reference in their entirety as is fully set forth herein. New architectures will be described in following sections.

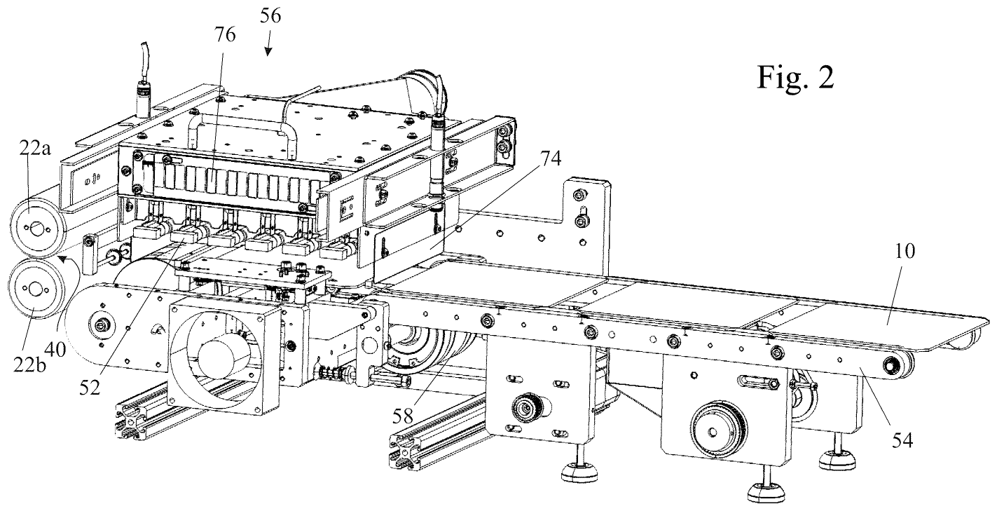

FIGS. 2 to 4 show an apparatus 56 for feeding substrates 10 to a nip 40 between two rollers 22a and 22b such as described above. The apparatus comprises two separately driven conveyors, herein termed a feeding (or feed) conveyor 54 and a transportation (or transport) conveyor 58, to distinguish them from one another. The purpose of the feeding conveyor is to transfer substrates 10, one at a time from a suitable supply, such as a stack or a cassette, to a location at which they can be picked up by the transportation conveyor 58. The purpose of the transportation conveyor 58 is first to establish an exact positioning (e.g., by way of a sensor detecting the positioning) of each substrate 10 and then to advance the substrate 10 at a predetermined speed to the nip 40 for it to arrive at the nip 40 at a time that is synchronised with the motion of the webs carrying the substrate patterns, so as to achieve correct registration between the patterns and the substrates.

As readily appreciated by persons skilled in registration of patterns on a surface or with respect to one another, such matters typically allow for some tolerance which may be expressed in relative terms (e.g., percentage of deviation) or in absolute terms (e.g., distance from intended positioning). For example, in the case of functional patterns, a registration may be deemed correct if within a tolerance of +/−100 micrometre (μm) or less, or +/−75 μm or less, or +/−50 μm or less from exact positioning. For illustration, the patterns are correctly registered if within +/−50 μm in each of the X-direction (the direction of movement of the conveyors 54 and 58) and the transverse Y-direction from the desired positioning with respect to the various (leading, trailing, right and left) edges of the substrate and, if patterns are applied on both the top and bottom surfaces of the substrate, if within +/−50 μm in each of the X-direction and Y-direction from the desired positioning with respect to one another. In the case of purely ornamental patterns, such tolerance can be further relaxed and a pattern applied within a few millimetres (mm) from its intended position may still be correctly registered if visually satisfactory for its desired decorative purpose.

The speed of the feeding conveyor 54 is controlled through an electric motor with its speed monitored using an encoder. The feeding conveyor 54 may comprise two spaced apart cyclically movable endless belts running parallel to one another, each side edge of the substrate 10 resting on, and supported by, a respective one of the two belts. As such, the belts should be spaced apart less than the width of the substrate 10 to be transported. The substrates 10 may be delivered to the feeding conveyor 54 by drawing substrates 10 from a stack or cassette or by a further station upstream of the feeding conveyor 54.

The reason that the feeding conveyor 54 is formed of two separate belts is that, at its downstream end, the two belts straddle the upstream end of the transportation conveyor 58 creating an overlap region at which the individual substrates are transferred from the feeding conveyor 54 to the transportation conveyor 58. The transfer between the conveyors is described in more detail below with respect to one embodiment wherein the feeding conveyor is in a plane higher than the plane of the transportation conveyor, the substrates being individually lowered from the former to the latter conveyor. The skilled person would know how to adapt the apparatus for the converse case of the feeding conveyor being in a plane lower than the plane of the transportation conveyor, the substrates being individually lifted up from the former to the latter conveyor.

In some embodiments, one or more of inspecting, selecting, laser doping or any other process may be carried out while the substrates 10 lie on the feeding conveyor 54. In other embodiments, the feeding conveyor 54 acts purely as a means of transferring substrates 10 from a stack or cassette to a transportation station, generally designated 56.

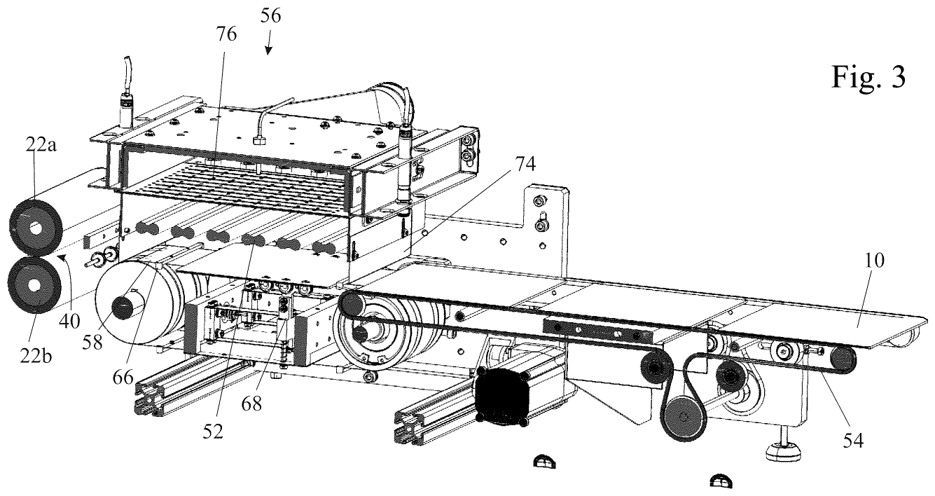

The transportation station 56 comprises the transportation conveyor 58, the latter being formed as an endless belt having at least one projection 66, which is shown in FIG. 3 as a bar 66 extending transversely, e.g., across the entire width of the belt, any other dimension adapted to the size and/or intended position of the substrate being acceptable. For instance, the projection may be shaped as a pin located across the width of the conveyor to suitably contact the substrate, such projection being optionally capable of facilitating the registration of the substrate with respect to the nip. The projections are intended to engage the trailing edge of a substrate 10 being advanced towards the nip 40. Because the substrates are advanced by pushing them from their rear edge, rather than relying on the friction of the conveyor, the position of each substrate is accurately determined as it is being advanced towards the nip 40. The transportation conveyor 58 may be dimensioned to have only a few (e.g., 2, 3 . . . ) projections over its entire circumference, so that only a single whole substrate 10 can be transported by it at any one time towards the nip 40. This may be desirable for a number of reasons, including preventing the registration between one substrate 10 and the web affecting the next, and minimising loss of substrates in the event of a shutdown.

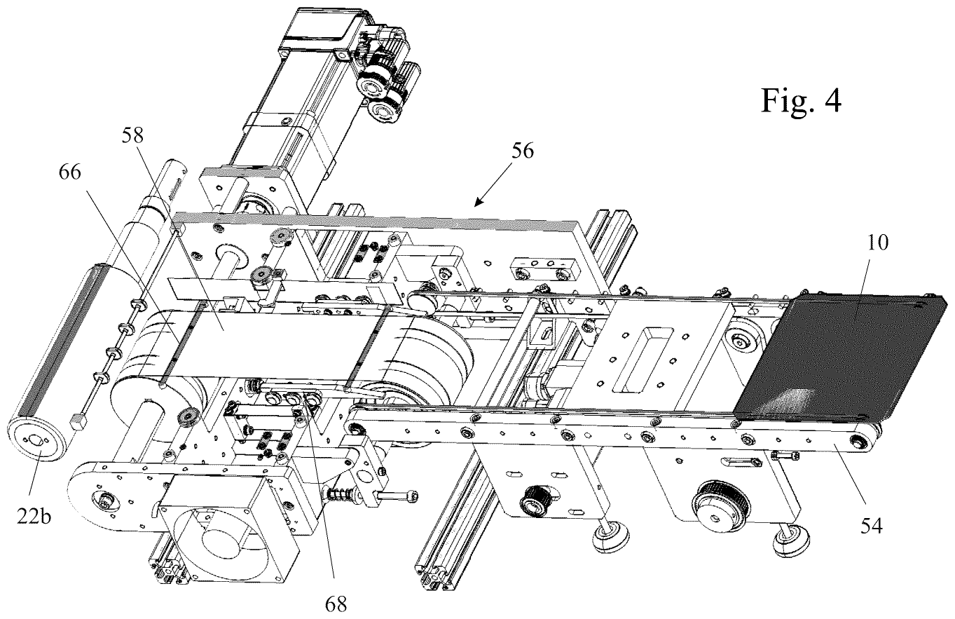

In the exemplary illustrated embodiment, the plane of the feeding conveyor 54 is higher than that of the transportation conveyor 58, but this should not be construed as limiting. In the overlap region, the feeding conveyor drives substrates onto a lifting mechanism 68 (best seen in FIGS. 3 and 4) that supports a single substrate by its lateral edges in a plane higher than that of the transportation conveyor 58. After a substrate 10 has been loaded onto it by the feeding conveyor 54, the lifting mechanism 68 lowers the substrate that it supports to a position, above the plane of the transportation conveyor, where it will collide with a projection 66 on the transportation belt, resulting in the substrate 10 sliding off the lifting mechanism 68 and onto the belt of the transportation conveyor 58, with its trailing edge in contact with the projection 66. The lifting mechanism 68 moves in synchronism with the transportation conveyor 58 so that it only moves to its lower position at times when there is no projection located beneath it. This can be achieved, for example, by the lifting mechanism 68 being operated by a cam rotated in synchronism with transportation belt, or by initiating descent of an independently driven lifting mechanism 68 by means of a sensor associated with the transportation conveyor 58.

To decrease the chance of the substrate 10 breaking on colliding with a bar 66, the frame of the lifting mechanism 68 on which the substrate sits may have a low coefficient of friction. This may be achieved using bearing elements, by treating or coating the lifting mechanism 68 with a low friction material, or simply by polishing the frame of the lifting mechanism 68.

The speed of the transportation conveyor 58, as well as the speed of the web 14, may be varied to synchronise the substrate 10 and the pattern on the web 14. Sensors may be disposed in the transportation station 56 to monitor the position of the projections 66 and/or the substrate 10, and particularly its leading edge. In the case of two webs being used to apply a pattern to opposite sides of the substrate 10, at least one of the webs may be driven at a constant surface velocity. The speed of the transportation conveyor 58 is lower than the surface velocity of the web(s) at the nip 40 to ensure that as the leading edge of the substrate 10 contacts the nip 40, it is pulled away from the projection 66. Were the speed of the transportation conveyor 58 to exceed the speed of passage of the substrate through the nip 40, the projection 66 would impart a compressive force to the substrate in a lengthways direction, which in turn might increase the risk of breakage. As readily appreciated, the present teachings therefore relate to an apparatus (and related method) wherein the nip grips the leading edge of the substrate in absence, at such time, of any force from the transport conveyor that would result in compression being applied to the edges of the substrate. The edges of the substrate along the X- and Y-direction are typically more fragile than more central portions of the substrate and the present apparatus may therefore preserve their integrity, the substrate being robust enough to be subjected to, and/or the nip being adapted to apply, a compression in the Z-direction high enough to ensure transfer and low enough to prevent breakage.

Correct alignment between the pattern carried by a web and the substrate onto which it is to be transferred, in the X-direction as defined above, is ensured by correctly timing the movement of the transportation conveyor. Alignment in the transverse Y-direction may be ensured by urging the substrate, in the transverse direction, while it is on the transportation conveyor 58. Because of the positive engagement of the trailing edge of a substrate with a projection 66 of the transportation conveyor, there is no risk of the action of aligning the substrate in the Y-direction interfering with position of the substrate in the X-direction.

If the projection 66 on the transportation conveyor contacts with the trailing edge of a substrate at more than one point and the element urging the substrate against a guide to achieve alignment in the Y-direction also makes contact with the side edge of the substrate at more than point, then there is a risk of the substrate being skewed (rotating about a vertical axis) while trying the achieve alignment in the Y-direction. In order to ensure that the substrate arrives at the nip with a desired orientation, it is preferable for the projection 66 to make only point contact with the trailing edge of the substrate, and to provide two or more pushers positioned on one side of the transportation conveyor to urge the substrate against an elongate guide surface positioned on the opposite side of the transportation conveyor. The guide surface can be a continuous bar having a low friction surface or a series of rollers in sufficient proximity one to another (e.g., in rolling contact), so as to constitute an elongate guide surface. The pushers can be spaced from one another in the direction of travel of the substrate and may comprise rollers urged towards the substrate by means of springs. The spacing of the pushers and the timing of their contacting a lateral edge of the substrate are adapted to prevent the pushers from contacting corners of the substrates, which can be relatively more fragile. The engagement and disengagement of the pushers with the substrate can be controlled by a cam system referred to the position of the substrate along the X-direction.

Such an arrangement will ensure that one side of the substrate will make contact at two points with the guide surface and at only one point with the projection on the transportation conveyor. When there are only three contact points, the risk of skewing of the substrate is avoided. The pushers facilitate the registration of the substrate in the Y-direction, while the projection contributes to the registration of the substrate in the X-direction, such registration of the substrate in X- and Y-directions being with respect to the nip.

If a pattern is to be applied on a single side of the substrate, the registration of the web with respect to the nip may be superfluous, as long as a proper registration of the substrate ensures proper timing of transfer, hence positioning of the pattern on one side of the substrate. Still, tension rollers along the path of the web may facilitate such alignment between the substrate and the pattern to be transferred. When patterns are to be applied on both sides from two webs, either at two subsequent nips but more typically at a same nip, then tension rollers along the path of at least one of the two webs is required to ensure proper alignment, at least of the two webs one with another. The presence of tension rollers along each of the paths of both webs may further facilitate the process.

It should be mentioned in this context that because of the rigidity of certain substrates, notably semiconductor wafers, even when a straight edge of a substrate is urged against a straight guide, there will only be two points of contact at which force is transferred from one to the other.

If one were merely to allow substrates to transfer at random times between the feed conveyor and the transport conveyor, in the overlap region between the two conveyors, there would be a risk of a substrate at least partially resting on the top of one of the projections 66. The lifting mechanism 68 described above is intended to safeguard against such an eventuality. The lifting mechanism maintains each substrate clear of the projections 66 and lowers it in synchronism with the movement of the transportation belt 58 to ensure that it is picked up by the next projection to pass the lifting mechanism.

The use a lifting mechanism is only one way of overcoming the problem of disparity in speed between feeding and transportation conveyors, while ensuring that a projection contact the trailing edge of the substrate. In an alternative embodiment, there may be provided an overlap region between the two conveyors 54, 58 and a friction element on the transport conveyor may engage a substrate 10 upon transfer from the feeding conveyor 54 to the transportation conveyor 58 to reduce its speed and ensure that a projection 66 of the transportation conveyor 58 should contact the trailing edge of the substrate. Correct timing of the two conveyors 54 and 58 would prevent the substrate from landing on a projection during the transfer. Suitable timing ensures that the substrates can be individually fed (placed onto the transport conveyor) in a volume swept by the projections.

The distance between projections along the length of the conveyor belt in X-direction needs to be sufficient for friction element/lifting mechanism to work correctly. The distance between the projections flanking a feeding volume needs to be at least 10% greater than dimension of the substrate.

The lifting mechanism can also prevent the substrate that is currently on it from being affected by the registration of the substrate on the transportation conveyor—i.e. by only lowering the substrate after the leading edge of the substrate before it has entered the nip, as mentioned above. This is an important advantage of a lifting mechanism over a friction element.

A presence sensor may be provided between the feeder and transportation conveyors, to commence movement of the transportation conveyor 58 when a substrate is detected in the feeder conveyor 54. The presence sensor can be used to adjust the speed of the feeder conveyor 54 to ensure that substrates are fed onto the transportation conveyor 58 at the right time (e.g., with respect to the position of a projection able to engage a trailing edge of a substrate transferred from the feeding to the transportation conveyor). Additional sensors can be provided to assess the registration of the substrate with respect to the nip and synchronize the arrival of its leading edge with the desired positioning of a pattern to be transferred thereto from a web.

The lifting mechanism 68 maybe a cam and follower mechanism, a piston mechanism, or any other mechanism known in the art.

Alternatively, or as a secondary check, a system (not shown) may be installed further downstream to straddle the transportation conveyor 58. Such a system may comprise one or more guide rails to correctly align the substrates 10. If installed in addition to the pushers that can be used to facilitate the alignment of the substrates in the Y-direction, the guide rail(s) may be positioned upstream of the pushers to provide a preliminary alignment.

The transportation station 56 may further comprise a heater 52 which can serve to heat the substrate 10 to a desired temperature prior to its entry into the nip. In a similar manner, a heater may be positioned along the path of the web to raise its temperature prior to contacting the substrate. Alternatively, or additionally, if an adhesive coating is applied on the substrate or on a web, or on selected regions thereof, and if the adhesive used in such coating is heat activatable (optionally in addition to being pressure activatable), then a heater may be positioned downstream an applicator adapted to apply the adhesive coating.

The desired temperature at any of these locations may be one that may activate the adhesive in the composition carried by the web 14, for instance if the composition includes an adhesive which is thermally activated, and need not be the same for the substrate and each of the webs. The appropriate heating temperature will depend on the nature of the composition and the adhesive, and the materials the webs and substrates are made of and is discussed in more detail in WO 2018/020479 and US 2019/0172967. By way of illustration, the heating temperature may depend upon the softening temperature of the composition and of adhesives therein, and may therefore differ for each side of a same substrate the patterns being applied from different webs optionally comprising distinct substances and/or arrangements thereof. In embodiments where heaters are utilized, care is taken to configure any necessary apparatus and parts thereof (e.g., contacting or adjacent the heated web and/or heated substrate) to withstand the heat without distortion or failure.

The heating may take different forms depending on the temperature to be reached and can be by conduction, convection or radiation. While webs can also be heated by radiation as described in the following with respect to the substrates, they are typically heated, when desired, with hot air or by contact with heated elements (e.g., heated rollers).

In embodiments where the substrate is heated by radiation, the heater 52 may include one or more infrared lamps positioned above and/or below the transportation conveyor 58. Heating lamps positioned on both sides of the substrate 10 may be utilised together when the substrate 10 is thick, e.g., over about 1 mm, to ensure even heating. Where such heating is required, the transportation conveyor 58 may be split much like the feeding conveyor 54, i.e. it may comprise two thin synchronised belts each supporting one side of the substrate, and each may comprise respective projections to push the substrate 10 from both sides.

In some embodiments, the infrared lamps comprised in heater 52 may be configured to collectively emit radiation that is equivalent to about 6 kW, 12 kW, 24 kW or any other appropriate amount of radiation. Shields 74 may be provided to block the radiation from the lamps reaching outside the heating area. A cooling apparatus 76 may be provided to prevent overheating of the shields. The cooling apparatus may comprise air cooling components or any other means known in the art.

While heating can be performed upstream of the nip for the web(s) and/or substrate, it can alternatively or additionally be performed at the nip. For instance, the pressure roller 22 may, in some embodiments, additionally serve as a heating roller. Heating the web and/or the substrate upstream of the nip may obviate the need for any heating of the nip or it may allow for heating the nip to a lower temperature. In some embodiments, the heating may occur even prior to the transportation station 56, although the nearer to the nip 40 that the heating occurs, the more efficient the process. If performed at more than one location and/or towards more than one the substrate and one of the webs, the different heating temperatures that may be set to provide a gradual change in temperatures as the substrate and the web(s) proceed to a nip. Such gradients can be selected to avoid too rapid a rise, or conversely too rapid a drop, in temperature which may adversely affect the transfer of a pattern from a web to an intended surface of the substrate. Temperature sensors may be incorporated into the apparatus to ensure temperatures are within an acceptable range, and controllers (manual or computer controlled) provided to keep the temperatures within their respectively acceptable ranges.

As mentioned above, only one substrate 10 may, in some embodiments, be placed on the transportation conveyor 58 at any one time so that waste is minimised in the event of a shutdown. For example, if a shutdown occurs whilst a substrate 10 is part way through the heater, the substrate may be considered scrap if it has only been partially heated and then allowed to cool, or if it has been overheated due to the conveyor 58 stopping in the heating area. This may be mitigated by using a shutdown procedure where each station is shutdown sequentially as it passes a final substrate 10 on to the next station. For example, the transportation station 56 may only shutdown once the leading edge of the final substrate 10 has entered the nip 40. In a such a case, a few of the substrates salvaged from irreversible processing by this sequential shutdown need not be wasted and could be recycled.

Following passage through the nip, the web can be separated (e.g., peeled away) from the substrate, such separation, if occurring, completing the transfer of the substance pattern from a web to the substrate. The substrate and the web(s) may be cooled downstream of the nip to assist separation. As the cooling is believed to accelerate or otherwise facilitate the adherence of the substance pattern to the substrate and/or ease the release of the pattern from the flexible web, the appropriate cooling temperature and/or cooling rate will depend on the nature of the composition and of its components. Regardless of the means employed to ensure cooling of the substrates and/or webs, the site and/or device where such cooling takes place, if desired, can be referred to as a cooling station.

The separation device 30 illustrated in the exemplary embodiment of the depicted apparatus comprises a metal plate that is bent about a small radius to define an acute angle. The web on its return path to the take-up roller 32 is bent over the sharp edge defined by the outer sides of the bent metal plate. This action peels the web 14 away from the substrate 10 leaving the composition adhering to the substrate 10. A skilled person will readily appreciate that similar satisfactory peeling of the web 14 can be achieved by the angle formed between the path of web 14 and the path of substrate 10 or by alternative separation devices. Regardless of the means employed to ensure peeling of the web from the surface of the substrate, the site and/or device where such separation takes place, if desired, can be referred to as a separation or separating station. The cooling station and separation station are non-limiting examples of stations downstream of the nip where the substrates and the webs can be subjected to any desired action, these stations being also referred to as post-transfer stations.

The substrate now bearing at least part of a desired pattern on at least one of its sides can, if needed, be further treated. For instance, it may be exposed to energy in an amount sufficient to cause sintering and/or fusing of metal particles contained in the substance so as to render the transferred pattern conductive, it may be cured by radiation if the substance includes a curable material that may further adherence to the substrate. In the event that a web is not peeled away from the substrate, the treatment taking place following the nip may include separating between individual substrates that would be otherwise “linked” by way of attachment to a common web (e.g., by cutting the web in-between adjacent substrates). Such post-treatment can be performed off-line in a separate apparatus (e.g., a solar cell furnace) or in-line with an apparatus according to the present teachings. A variety of post-treatments exist depending on the substrate, the transferred pattern and the intended use, and are known to the skilled persons, hence shall not be herein detailed. The sites or devices where such post-treatment of the substrates and the webs may take place, whether still attached one to another or separated, can be referred to as post-treatment stations. Post-treatment stations can be considered another kind of post-transfer stations.

Although the present disclosure has been described with respect to various specific embodiments presented thereof for the sake of illustration only, such specifically disclosed embodiments should not be considered limiting.

It is therefore to be understood that the foregoing description including the specifically described apparatuses are merely exemplary of the presently disclosed subject matter, are presented for the sake of illustration only, and are therefore not intended to be necessarily limiting. Furthermore, all examples, embodiments, implementations, cases, instances, figures/illustrations, etc. of such features described herein should be understood to be non-limiting. Many other alternatives, modifications, alterations, permutations, and variations of such features will be apparent to those skilled in the art based upon the disclosure herein. Accordingly, it is intended to embrace all such alternatives, modifications and variations, and any change which come within their meaning and range of equivalency.

The word “exemplary” is used herein to mean “serving as an example, instance or illustration”. Any example, embodiment, case, instance, or figure/illustration of a certain feature described as “exemplary” is not necessarily to be construed as preferred or advantageous over other embodiments and/or to exclude the incorporation of one or more features from other embodiments. Furthermore, a feature which is described as preferred or advantageous in some embodiments, may not necessarily be preferred or advantageous in other embodiments.

It is appreciated that certain features of the presently disclosed subject matter, which are, for clarity, described in the context of different embodiments, may also be provided in combination in the same embodiment or embodiments. Conversely, various features of the presently disclosed subject matter, which are, for brevity, described in the context of the same embodiment or embodiments, may also be provided separately or in any suitable sub-combination or as suitable in any other described embodiment of the presently disclosed subject matter. Certain features described in the context of an embodiment are not to be considered essential features of the embodiment, unless the embodiment is inoperative without those features.

Unless otherwise defined or understood from the disclosure herein, all technical and scientific terms used herein have the same meaning as commonly understood by one of ordinary skill in the art to which the present disclosure pertains.

Unless otherwise stated, the use of the expression “and/or” between the last two members of a list of options for selection indicates that a selection of one or more of the listed options is appropriate and may be made.

In the description and claims of the present disclosure, each of the verbs “comprise”, “include” and “have”, and conjugates thereof, are used to indicate that the object or objects of the verb are not necessarily a complete listing.

As used herein, the singular form “a”, “an” and “the” include plural references and mean “at least one” or “one or more” unless the context clearly dictates otherwise.

As used herein, the term at least one of A and B is intended to mean either A or B, and may mean, in some embodiments, A and B.

Positional or motional terms such as “upper”, “lower”, “right”, “left”, “bottom”, “back”, “front”, “below”, “lowered”, “low”, “top”, “above”, “elevated”, “high”, “vertical”, “side”, “horizontal”, “backward”, “forward”, “upstream” and “downstream”, as well as grammatical variations thereof, may be used herein for exemplary purposes only, to illustrate the relative positioning, placement or displacement of certain objects (e.g., components in an apparatus), to indicate a first and a second object or to do both. Such terms do not necessarily indicate that, for example, a “bottom” object is below a “top” object, as such directions, components or both may be flipped, rotated, moved in space, placed in a diagonal orientation or position, placed horizontally or vertically, or similarly modified.

Unless otherwise stated, when the outer bounds of a range with respect to a feature of an embodiment of the present disclosure are noted herein, it should be understood that in the embodiment, the possible values of the feature may include the noted outer bounds as well as values in between the noted outer bounds. Herein, unless otherwise stated, adjectives such as “substantially”, “approximately” and “about” that modify a condition or relationship characteristic of a feature or features of an embodiment of the presently disclosed subject matter, are to be understood to mean that the condition or characteristic is defined to within tolerances that are acceptable for operation of the embodiment for an application for which it is intended, or within variations expected from the measurement being performed and/or from the measuring instrument being used. For example, when the term “about” and “approximately” precedes a numerical value, it may indicate +/−15%, or +/−10%, or even only +/−5%, or any other suitable +/− variation within such ranges, and in some instances may indicate the precise value. Furthermore, unless otherwise stated, the terms (e.g., numbers) used in an embodiment of the presently disclosed subject matter, even without such adjectives, should be construed as having tolerances which may depart from the precise meaning of the relevant term but would enable the embodiment or a relevant portion thereof to operate and function as described, and/or as understood by a person skilled in the art.

To the extent necessary to understand or complete the disclosure of the present disclosure, all publications, patents, and patent applications mentioned herein, including in particular the applications of the Applicant, are expressly incorporated by reference in their entirety as is fully set forth herein.

In addition to the features of the above disclosure that are claimed in the appended claims, features believed to be inventive in their own right are set out in the clauses below, to provide fair basis for eventual filing of one or more divisional patent applications.

Clause 1. An apparatus for transferring at least one substance pattern from a respective surface of at least one web to at least one surface of a substrate, the apparatus comprising a nip through which a substrate passes at the same time as at least one web, the nip comprising at least one pressure roller serving to press the surfaces of the at least one web and of the substrate against one another during passage through the nip; a web feeding mechanism and a substrate transportation mechanism, wherein the operations of the web feeding mechanism and of the substrate transportation mechanism are synchronised to ensure accurate positioning of the substance pattern on the surface of the substrate.

Clause 2. An apparatus for transferring at least one substance pattern from a respective surface of at least one web to at least one surface of a substrate, the apparatus comprising a nip through which a substrate passes at the same time as at least one web, the nip comprising at least one pressure roller serving to press the surfaces of the at least one web and of the substrate against one another during passage through the nip; a web feeding mechanism and a substrate transportation mechanism, wherein the transportation mechanism includes an alignment mechanism for ensuring correct positioning of the substrate in a direction transverse to the direction of movement towards the nip.

Clause 3. An apparatus as in clause 2, wherein the alignment mechanism serves additionally to ensure correct orientation of the edges of the substrate relative to the nip.

Clause 4. An apparatus as in clause 3, wherein the alignment device it operative to urge the substrate laterally such that edges of the substrate contact three reference points, at least one reference point contacting a trailing edge of the substrate.

Clause 5. An apparatus for transferring at least one substance pattern from a respective surface of at least one web to at least one surface of a substrate, the apparatus comprising a nip through which a substrate passes at the same time as at least one web, the nip comprising at least one pressure roller serving to press the surfaces of the at least one web and of the substrate against one another during passage through the nip; a web feeding mechanism and a substrate transportation mechanism, wherein the transportation mechanism includes a feeding conveyor, a transportation conveyor arranged downstream of and below the feeding conveyor, and a lifting mechanism for lowering substrates from the feeding conveyor onto the transportation conveyor.

Clause 6. An apparatus for transferring at least one substance pattern from a respective surface of at least one web to at least one surface of a substrate, the apparatus comprising a nip through which a substrate passes at the same time as at least one web, the nip comprising at least one pressure roller serving to press the surfaces of the at least one web and of the substrate against one another during passage through the nip; a web feeding mechanism and a substrate transportation mechanism, wherein the transportation mechanism further comprises a heater configured to heat at least one of the substrate and of the at least one web prior to delivery of the substrate and the web to the nip.

Clause 7. An apparatus for transferring substance patterns from respective surfaces of two webs onto opposite surfaces of a substrate, the apparatus comprising a nip through which a substrate passes at the same time as the two webs, the nip comprising two pressure rollers serving to press the surfaces of the two webs against the opposite surfaces of the substrate during passage through the nip; a respective web feeding mechanism associated with each web and a substrate transportation mechanism, wherein at least one of the web feeding mechanisms includes at least one tension roller for aligning the two webs with one another.

Clause 8. An apparatus for transferring substance patterns from respective surfaces of two webs onto opposite surfaces of a substrate, the apparatus comprising a respective web feeding mechanism associated with each web, a substrate transportation mechanism and two nips through which the substrate passes sequentially, each nip comprising a pressure roller serving to press the surface of a respective one of the two webs and a respective surface of the substrate against one another during passage through the nip.

1. A method of introducing a substrate into a nip and driving the substrate therethrough, the nip being defined between a pressure roller and an opposing surface, the method comprising advancing the substrate towards the nip by a transport conveyor configured to cease applying a force to a trailing edge of the substrate upon engagement of a leading edge of the substrate within the nip, the transport conveyor having upon said engagement a velocity lower than a velocity at which the substrate is driven through the nip.

2. A method for transferring a substance pattern to a substrate, the method comprising:
a—providing a nip formed between a pressure roller and an opposing surface, a rotation of the pressure roller driving a substrate through the nip upon engagement of a leading edge of the substrate within the nip, the nip having a linear nip velocity;
b—driving a web carrying the substance pattern to enter the nip simultaneously with the substrate;
c—advancing the substrate towards the nip in a X-direction of travel utilizing a transport conveyor including one or more projections coupled thereto, at least one of the projections engaging a trailing edge of the substrate, wherein upon engagement of a leading edge of the substrate within the nip, the transport conveyor advances the substrate at a velocity lower than the nip velocity.

3. A method as claimed in claim 2, wherein the transport conveyor has a first side and a second side parallel to the X-direction and opposite one another, and wherein the transport conveyor comprises two or more pushers disposed on the first side and an elongate guide surface disposed on the second side, the pushers being spaced from one another along the X-direction, the method further comprising urging the substrate in a Y-direction traverse to the X-direction against the elongate guide surface by using the pushers.

4. A method as claimed in claim 3, wherein the pushers urge the substrate towards Y-registration and the, or each, projection is adapted to provide X-registration of the substrate, each registration being with respect to the nip and/or to the substance pattern carried by the web.

5. A method as claimed in claim 2, wherein the substrate is loaded on the transport conveyor utilizing a feed conveyor placing individually the substrate into a volume swept by the one or more projections of the transport conveyor such that the trailing edge of the substrate is engaged by at least one of the projections.

6. A method as claimed in claim 5, wherein the feed conveyor and the transport conveyor overlap and straddle one another at an end of the transport conveyor distal from the nip.

7. A method as claimed in claim 5, wherein each of the transport conveyor and the feed conveyor comprises at least one cyclically movable endless belt.

8. A method as claimed in claim 5, wherein at least one of the transport conveyor and the feed conveyor comprises two parallel belts and the feed conveyor carries the substrates in a plane different than that of the transport conveyor, the method further comprising lifting up or down substrates individually from the feed conveyor into the volume swept by the one or more projections of the transport conveyor utilizing a lifting mechanism.

9. A method as claimed in claim 8, further comprising lowering stress placed on the substrate upon making contact with the at least one projection of the transport conveyor engaging the trailing edge by providing a low friction static interface, or a rolling interface, between the substrate and the lifting mechanism.

10. A method as claimed in claim 2, wherein the at least one of the projections on the transport conveyor engaging the trailing edge of the substrate is configured to make point contact therewith.

11. A method as claimed in claim 2, wherein the pressure roller is a first pressure roller and the opposing surface is stationary or formed by a second pressure roller, one web passing through the nip at the same time with the substrates being advanced by the transport conveyor, so that each substance pattern carried by the web is transferred to one side of each substrate.

12. A method as claimed in claim 11, further comprising at least one of:
a) tensioning the web by using at least one tension roller along a path of the web, the tensioning being adapted to provide X-registration of the web with respect to the nip and the substrate passing therethrough;
b) heating at least one of the substrates and the web prior to reaching the nip;
c) applying an adhesive to at least one of the substrates and the web prior to reaching the nip;
d) cooling at least one of the substrates and the web, subsequent to exiting from the nip;
e) separating the web from a surface of the substrates, subsequent to exiting from the nip or subsequent to cooling; and
f) post-treating the substrates subsequent to exiting from the nip, cooling or separation from the web, to modify the substance patterns and/or their adherence to the substrates.

13. A method as claimed in claim 2, wherein the pressure roller is a first pressure roller and the opposing surface is formed by a second pressure roller, two webs passing through the nip at the same time with the substrate, the two webs being constituted of a first web carrying a first substance pattern and a second web carrying a second substance pattern, and wherein the substrate is transported through the nip between the two webs, the first and second substance patterns being transferred to opposite sides of the substrate.

14. A method as claimed in claim 13, further comprising tensioning at least one of the two webs by using at least one tension roller along a path of the, or each, web, the tensioning being adapted to provide X-registration of the at least one web with respect to the other of the two webs.

15. A method as claimed in claim 13, further comprising heating at least one of the substrates and the webs prior to reaching the nip.

16. A method as claimed in claim 13, further comprising applying an adhesive to at least one of the substrates and the webs prior to contact being made therebetween upon reaching the nip.

17. A method as claimed in claim 13, further comprising subsequent to passage of the substrates through the nip at least one of: a) cooling the substrates and/or the webs, b) separating at least one of the webs from a surface of the substrate, and c) post-treating the substrates to modify the substance patterns and/or their adherence to the substrates transferred thereto.

18. A method as claimed in claim 17, wherein the substance patterns include particles of electrically conductive material; the method further comprising post-treating the substrates to render the pattern electrically conductive.

19. A method as claimed in claim 1, further comprising at least one of:
a) heating at least one of the substrates and the web prior to reaching the nip;
b) applying an adhesive to at least one of the substrates and the web prior to reaching the nip;
c) cooling at least one of the substrates and the web, subsequent to exiting from the nip;
d) separating the web from a surface of the substrates, subsequent to exiting from the nip or subsequent to cooling; and
e) post-treating the substrates subsequent to exiting from the nip, cooling or separation from the web, to modify the substance patterns and/or their adherence to the substrates.

20. A method as claimed in claim 19, wherein the substance patterns include particles of electrically conductive material and the substrate is a semiconductor wafer adapted for the manufacturing of a solar cell or an electrically insulating substrate adapted for the manufacturing of a printed circuit board; the method further comprising post-treating the substrates to render the pattern electrically conductive.
